(19) United States
(12) Patent Application Publication
(10) Pub. No.: US 2024/0423103 A1
(43) Pub. Date: Dec. 19, 2024

(54) AIR BRIDGE PREPARATION METHOD, QUANTUM CHIP, AND QUANTUM COMPUTER

(71) Applicant: TENCENT TECHNOLOGY (SHENZHEN) COMPANY LIMITED, SHENZHEN (CN)

(72) Inventor: Kunliang BU, Shenzhen (CN)

(73) Assignee: TENCENT TECHNOLOGY (SHENZHEN) COMPANY LIMITED, SHENZHEN (CN)

(21) Appl. No.: 18/817,491

(22) Filed: Aug. 28, 2024

Related U.S. Application Data
(63) Continuation of application No. PCT/CN2023/124036, filed on Oct. 11, 2023.

(30) Foreign Application Priority Data
Nov. 16, 2022 (CN) 202211438099.4

(51) Int. Cl. H10N 60/83; G06N 10/40; H01L 21/764; H01L 23/482; H01L 29/66; H10N 60/01

(52) U.S. Cl. CPC H10N 60/83; G06N 10/40; H01L 21/764; H01L 23/4821; H01L 29/66977; H10N 60/0884

(57) ABSTRACT

The present disclosure discloses an air bridge manufacturing method, a quantum chip, and a quantum computer, and relates to the field of quantum chip technologies. One method, performed by a photolithography device, includes constructing a bridge support structure for an air bridge on a substrate with a coplanar waveguide by using photoresist; performing ion beam milling processing on the substrate with the bridge support structure to obtain an initial air bridge, the ion beam milling processing being configured for denaturing photoresist on a surface layer of the bridge support structure; and performing light-illumination processing and photoresist removal processing on a photoresist region comprising denatured photoresist in the initial air bridge, to obtain the air bridge. Through embodiments of the present disclosure, a photoresist removal effect can be improved, and a success rate of air bridge manufacturing can be improved.

### RELATED APPLICATIONS

This application is a continuation application of PCT Patent Application No. PCT/CN2023/124036, filed on Oct. 11, 2023, which claims priority to Chinese Patent Application No. 202211438099.4, filed with the China National Intellectual Property Administration on Nov. 16, 2022, both of which are incorporated herein by reference in their entireties.

### FIELD OF THE TECHNOLOGY

Embodiments of the present disclosure relate to the field of quantum chip technologies, and in particular, to an air bridge preparation method, a quantum chip, and a quantum computer.

### BACKGROUND OF THE DISCLOSURE

In a superconducting quantum chip, microwave signals are transmitted through coplanar waveguides. Crosstalk occurs in microwave signals in different coplanar waveguides. To suppress the crosstalk between the signals, an air bridge structure may be used to connect infinite ground planes on two sides of the coplanar waveguide, to form a shielding layer, so as to suppress the crosstalk between the signals.

In a process of preparing the air bridge, a bridge support structure is prepared by using photoresist, a bridge body is prepared based on the bridge support structure, and after preparation is completed, the photoresist is removed, to obtain a bridging air bridge. In the related art, the photoresist is removed generally by using a resist remover.

However, an ion beam milling technology is required in the process of preparing the air bridge, which may denature photoresist on a surface layer, and for denatured photoresist, a removal effect of the resist remover is poor.

The present disclosure describes embodiments for manufacturing an air bridge, addressing at least one of the problems/issues discussed above, improving removal effect of the resist remover, improving the quality of air bridge manufacturing, increasing the application of air gaps in quantum chips/computers, and/or improving the field of quantum information processing and quantum computing.

### SUMMARY

Embodiments of the present disclosure provide an air bridge preparation method, a quantum chip, and a quantum computer. Technical solutions are as follows.

The present disclosure describes a method for manufacturing an air bridge, performed by a photolithography device. The method includes constructing a bridge support structure for an air bridge on a substrate with a coplanar waveguide by using photoresist; performing ion beam milling processing on the substrate with the bridge support structure to obtain an initial air bridge, the ion beam milling processing being configured for denaturing photoresist on a surface layer of the bridge support structure; and performing light-illumination processing and photoresist removal processing on a photoresist region comprising denatured photoresist in the initial air bridge, to obtain the air bridge.

The present disclosure describes an apparatus for manufacturing an air bridge. The apparatus includes a photolithography device; a memory storing instructions; and a processor in communication with the memory. When the processor executes the instructions, the processor is configured to cause the photolithography device to construct a bridge support structure for an air bridge on a substrate with a coplanar waveguide by using photoresist; perform ion beam milling processing on the substrate with the bridge support structure to obtain an initial air bridge, the ion beam milling processing being configured for denaturing photoresist on a surface layer of the bridge support structure; and perform light-illumination processing and photoresist removal processing on a photoresist region comprising denatured photoresist in the initial air bridge, to obtain the air bridge.

The present disclosure describes a non-transitory computer-readable storage medium, storing computer-readable instructions. The computer-readable instructions, when executed by a processor in an apparatus comprising a photolithography device, are configured to cause the photolithography device to: construct a bridge support structure for an air bridge on a substrate with a coplanar waveguide by using photoresist; perform ion beam milling processing on the substrate with the bridge support structure to obtain an initial air bridge, the ion beam milling processing being configured for denaturing photoresist on a surface layer of the bridge support structure; and perform light-illumination processing and photoresist removal processing on a photoresist region comprising denatured photoresist in the initial air bridge, to obtain the air bridge.

According to another aspect, an embodiment of the present disclosure provides an air bridge preparation method, performed by a photolithography device, the method including:
preparing a bridge support structure of an air bridge on a substrate with a coplanar waveguide by using photoresist;
performing ion beam milling processing on the substrate having the bridge support structure, and preparing the air bridge after the ion beam milling processing is performed, to obtain an initial air bridge, the ion beam milling processing being configured for denaturing photoresist on a surface layer of the bridge support structure; and
performing lighting processing and resist removal processing on a photoresist region including denatured photoresist in the initial air bridge, to obtain the air bridge.

According to another aspect, an embodiment of the present disclosure provides an air bridge preparation apparatus, including:
a first preparation module, configured to prepare a bridge support structure of an air bridge on a substrate with a coplanar waveguide by using photoresist;
a second preparation module, configured to perform ion beam milling processing on the substrate having the bridge support structure, and prepare the air bridge after the ion beam milling processing is performed, to obtain an initial air bridge, the ion beam milling processing being configured for denaturing photoresist on a surface layer of the bridge support structure; and
a processing module, configured to perform lighting processing and resist removal processing on a photoresist region including denatured photoresist in the initial air bridge, to obtain the air bridge.

According to another aspect, an embodiment of the present disclosure provides a photolithography device, including a photolithography component, a processor, and a memory. The memory has at least one instruction stored therein. The at least one instruction is loaded by the processor and controls the photolithography component, to implement the air bridge preparation method according to the foregoing aspect.

According to another aspect, an embodiment of the present disclosure provides a quantum chip, including the air bridge according to the foregoing aspect.

According to another aspect, an embodiment of the present disclosure provides a quantum computer, including the quantum chip according to the foregoing aspect.

In the embodiments of the present disclosure, resist removal is performed after the initial air bridge is prepared based on the photoresist, and during the resist removal, a process of lighting processing is added, so that the denatured photoresist formed during the ion beam milling can be removed. The solution provided in the embodiments of the present disclosure is used, so that the denatured photoresist that is difficult to remove can be removed in a simple operating manner. Compared with a resist removal manner by using only the resist remover, the solution provided in the embodiments of the present disclosure can improve a resist removal effect, and reduce resist removal time. This helps improve resist removal efficiency, so as to improve a success rate of air bridge preparation.

### BRIEF DESCRIPTION OF THE DRAWINGS

FIG. 1 is a schematic structural diagram of an air bridge according to an exemplary embodiment of the present disclosure.

FIG. 2 is a flowchart of an air bridge preparation method according to an exemplary embodiment of the present disclosure.

FIG. 3 is a flowchart of an air bridge preparation method according to another exemplary embodiment of the present disclosure.

FIG. 4 is a schematic cross-sectional view of a process of preparing a bridge support structure according to an exemplary embodiment of the present disclosure.

FIG. 5 is a schematic cross-sectional view of a process of preparing a basic bridge body according to an exemplary embodiment of the present disclosure.

FIG. 6 is a schematic cross-sectional view of preparing an initial air bridge according to an exemplary embodiment of the present disclosure.

FIG. 7 is a schematic diagram of a hole in an integral air bridge according to an embodiment of the present disclosure.

FIG. 8 is a flowchart of an air bridge preparation method according to another exemplary embodiment of the present disclosure.

FIG. 9 is a flowchart of an air bridge preparation method according to another exemplary embodiment of the present disclosure.

FIG. 10 is a result comparison diagram between a resist removal method according to an embodiment of the present disclosure and a resist removal method in the related art.

FIG. 11 is a diagram of a resist removal effect according to an embodiment of the present disclosure.

FIG. 12 is a structural block diagram of an air bridge preparation apparatus according to an embodiment of the present disclosure.

### DESCRIPTION OF EMBODIMENTS

To make the objectives, technical solutions, and advantages of the present disclosure clearer, the following further describes implementations of the present disclosure in detail with reference to the accompanying drawings.

“Plurality of” mentioned in the specification means two or more. “And/or” describes an association relationship between associated objects and represents that three relationships may exist. For example, A and/or B may represent the following three cases: Only A exists, both A and B exist, or only B exists. The character “/” in this specification generally indicates an “or” relationship between the associated objects.

First, terms described in the embodiments of the present disclosure are briefly introduced.

Coplanar waveguide: The coplanar waveguide is also referred to as a coplanar microstrip transmission line, including a center conductor (also referred to as a center strip) and semi-infinite ground planes (also referred to as ground strips) on two sides.

Air bridge: The air bridge is a three-dimensional bridge structure prepared by using a superconducting material, and is usually disposed on a bottom sheet. The air bridge is configured to connect infinite ground planes on the two sides of the coplanar waveguide, or connect center conductors of the two discrete coplanar waveguides. Air bridges may be classified into discrete air bridges and integral air bridges. A difference between the discrete air bridge and the integral air bridge lies in whether a bridge body of the air bridge is continuous.

Ion beam milling: The ion beam milling refers to bombarding a surface of a material by using an ion beam in a specific direction, to remove an oxide layer on the surface of the material.

The air bridge may be applied to a chip, such as a superconducting quantum chip. The superconducting quantum chip transmits microwave signals through the coplanar waveguides. Crosstalk occurs in microwave signals in different coplanar waveguides. When a density of the coplanar waveguide is high, the crosstalk between the signals is more severe. In a possible implementation, an air bridge may be prepared to connect the infinite ground planes on the two sides of the coplanar waveguide. The air bridge may form a shielding layer on a core wire of the coplanar waveguide, to suppress the crosstalk between the signals. In addition, an equipotential body may be formed by connecting, by the air bridge, the infinite ground planes on the two sides of the coplanar waveguide, to resolve a problem of a potential difference between the ground planes. In addition, the air bridge may be further used for cross-lines of two independent coplanar waveguides, to optimize a chip wiring problem.

The air bridge includes a bridge pier and a bridge body. In a process of preparing the air bridge, a bridge support structure may be first prepared, then the air bridge, namely, the bridge pier and the bridge body, is prepared based on the bridge support structure, and after the air bridge is prepared, the bridge support is released, so that preparation of the air bridge is completed.

In some embodiments, in a process of releasing the bridge support, an opening structure running through a bridge deck may be disposed on the bridge deck, and an etching material is released from an opening position to etch a bridge support material, so that the bridge support is released. In other words, the process of releasing the bridge support may be represented as a process of etching the bridge support material.

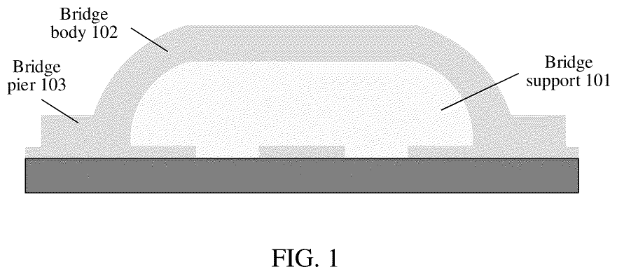

FIG. 1 is a side view of an air bridge. A bridge support 101 is first prepared, a bridge body 102 and a bridge pier 103 are prepared based on the bridge support 101, to obtain an air bridge structure, and then the bridge support 101 is released through a process means, to obtain an air bridge.

In some embodiments, the air bridge may be an SiO₂-based type air bridge, and the bridge support material is SiO₂. Alternatively, the air bridge may be a photoresist type air bridge, and the bridge support material is photoresist.

In a process of preparing the air bridge, usually an ion beam milling technology needs to be used to remove an oxide layer on a surface of the coplanar waveguide corresponding to a bridge pier region, to enable the air bridge to be connected to the ground planes on the two sides of the coplanar waveguide, so that the air bridge has good superconducting contact with the coplanar waveguide. However, during ion beam milling, an entire surface of a sample is bombarded by ions, where photoresist on the surface of the sample is denatured to generate denatured photoresist.

In the related art, during removal of the photoresist, a resist remover is usually used. However, the denatured photoresist is difficult to remove by using the resist remover (in particular, denatured photoresist in a region adjacent to the air bridge structure is difficult to remove), and residual denatured photoresist affects performance of a superconducting qubit. Therefore, an embodiment of the present disclosure provides an air bridge preparation method, for removing denatured photoresist, to improve a success rate of air bridge preparation and avoid an impact on a superconducting quantum chip. The method provided in this embodiment of the present disclosure is exemplarily described below.

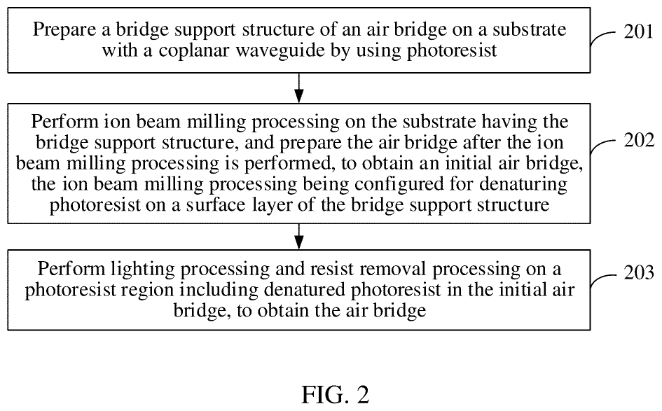

FIG. 2 is a flowchart of an air bridge preparation method according to an exemplary embodiment of the present disclosure. An example in which the method is applied to a photolithography device is used for description in this embodiment. The method includes the following operations.

Operation 201: Prepare a bridge support structure of an air bridge on a substrate with a coplanar waveguide by using photoresist.

In a possible implementation, the air bridge is configured to connect infinite ground planes on two sides of the coplanar waveguide. The photolithography device may first prepare the substrate with the coplanar waveguide, to prepare the air bridge on the substrate, so that the air bridge is in superconducting contact with the ground planes on the two sides of the coplanar waveguide, to implement a bridge connection.

In some embodiments, the substrate may be a high-resistance silicon substrate or a sapphire substrate. The coplanar waveguide may be prepared through a photolithography process based on a superconducting material (such as aluminum (Al), niobium (Nb), tantalum (Ta), or titanium nitride (TiN)). A specific superconducting material is not limited in the embodiments of the present disclosure.

In a process of preparing the air bridge, the photolithography device first prepares the bridge support structure on the substrate by using the photoresist. The bridge support structure is configured to support the air bridge. A bridge shape of a finally formed air bridge is the same as a bridge shape of the bridge support structure. In addition, a height of the air bridge is related to a thickness of the photoresist, and the thickness of the photoresist may be adjusted based on a height requirement of the air bridge.

In some embodiments, the photoresist needs to be photoresist having a high-temperature reflux characteristic, so that the photolithography device can change a sidewall shape of the photoresist by high-temperature reflux, to form an arc-shaped resist surface (in a bridge arch shape), and can prepare the bridge support structure on the substrate.

Operation 202: Perform ion beam milling processing on the substrate having the bridge support structure, and prepare the air bridge after the ion beam milling processing is performed, to obtain an initial air bridge, the ion beam milling processing being configured for denaturing photoresist on a surface layer of the bridge support structure.

After the bridge support structure is prepared on the substrate, the photolithography device can prepare a bridge body and a bridge pier of the air bridge by using a superconducting material on the bridge support structure. The bridge pier of the air bridge is configured to be in contact with the ground planes on the two sides of the coplanar waveguide on the substrate. In an atmospheric environment, a natural oxide layer is formed on a surface of the coplanar waveguide. Therefore, before preparing the bridge body and the bridge pier, the photolithography device needs to remove, through an ion beam milling technology, the natural oxide layer on the coplanar waveguide connecting the bridge pier region, so that the prepared air bridge has good superconducting contact with the coplanar waveguide. After the natural oxide layer is removed, the photolithography device may prepare the bridge body and the bridge pier of the air bridge on the bridge support structure by using the superconducting material, to obtain the initial air bridge.

The initial air bridge is an air bridge from which the bridge support structure is not released, namely, an air bridge on which resist removal processing is not performed. In some embodiments, the superconducting material for preparing the air bridge may be the same as or may be different from the superconducting material of the coplanar waveguide. This is not limited in this embodiment.

During ion beam milling, the ion beam milling performs indiscriminate bombardment on a to-be-bombarded region. Therefore, in addition to the coplanar waveguide connecting the bridge pier, another region on the substrate is also bombarded by an ion beam, including the bridge support structure on the substrate. In this way, due to the ion bombardment, the photoresist on the surface layer of the bridge support structure is denatured. Therefore, in a subsequent process of releasing the bridge support structure, that is, in a process of removing the photoresist configured for preparing the bridge support structure, the photolithography device further needs to remove the denatured photoresist.

Operation 203: Perform lighting processing and resist removal processing on a photoresist region including denatured photoresist in the initial air bridge, to obtain the air bridge.

After the initial air bridge is obtained, a final air bridge may be obtained by performing resist removal processing on the photoresist included in the initial air bridge. In this embodiment of the present disclosure, during resist removal, the photolithography device may perform the lighting processing and the resist removal processing on the photoresist region in the initial air bridge, so that the denatured photoresist is easily removed.

The resist removal process may include two processes: immersion by using the resist remover and mega sound cleaning. In some implementations, a mega sound may refer to sound having frequencies ranging from a fraction to several/tens of 10\hat{ }6 Hz (MHz), for non-limiting examples, the sound frequencies may be from 0.4 to 5 MHz. A mega sound cleaning may use high-frequency sound waves (e.g., a mega sound) to gently dislodge/remove small particles from a fabricated structure when the fabricated structure is immersed in the mega sound cleaning bath.

In a possible implementation, after performing the lighting processing on the initial air bridge, the photolithography device may perform, by using the resist remover, immersion processing on the initial air bridge after the lighting processing is performed, and perform mega sound cleaning on the initial air bridge by using a mega sound cleaning machine after the immersion is completed.

In another possible implementation, the photolithography device may simultaneously perform lighting processing on the initial air bridge in a process of immersing the initial air bridge in the resist remover, to improve photoresist removal efficiency, and perform mega sound cleaning on the initial air bridge by using the mega sound cleaning machine after the immersion is completed.

In comparison to a conventional manner of immersion by using the resist remover, in this embodiment of the present disclosure, lighting processing is performed on the initial air bridge, so that immersion time in the resist remover can be shortened, and resist removal efficiency can be improved. Subsequently, during the mega sound cleaning, only weak mega sound cleaning needs to be used to remove the denatured photoresist, and strong mega sound cleaning does not need to be used. This can avoid a problem of collapse of the air bridge caused by an excessively high mega sound cleaning intensity, ensure structural stability of the air bridge, and help improve a bridge formation rate of the air bridge. In some implementations, a weak mega sound cleaning may refer to a mega sound cleaning process by using mega sound with relative smaller frequencies and/or a relative lower power. For a non-limiting example, a weak mega sound cleaning may refer to a mega sound cleaning process by using mega sound at a frequency less than 1500 10\hat{ }3 Hz (kHz) and a power less than 75 Watts (W). In some implementations, a weak mega sound cleaning may refer to a mega sound cleaning process by using a mega sound cleaning machine operating at by using mega sound with relative smaller frequencies and/or a relative lower power, for a non-limiting example, 1000 kHz and 50 W for 20 minutes.

In conclusion, in the embodiments of the present disclosure, the resist removal processing is performed after the initial air bridge is prepared based on the photoresist, during the resist removal, a process of lighting processing is added, so that the denatured photoresist formed during the ion beam milling can be removed. The manner provided in the embodiments of the present disclosure is used, so that the denatured photoresist that is difficult to remove can be removed in a simple operating manner. Compared with a resist removal manner by using only the resist remover, the solution provided in the embodiments of the present disclosure can improve a resist removal effect, and reduce resist removal time. This helps improve resist removal efficiency, so as to improve a success rate of the air bridge preparation.

In this embodiment of the present disclosure, the air bridge is prepared based on the photoresist. A preparation process of the air bridge is described below by using an exemplary embodiment. In the present disclosure, a preparation process of the air bridge may refer to a manufacturing process of the air bridge or air bridge manufacturing; the air brige preparation may refer to the air bridge manufacture; and/or the preparing air bridge may refer to manufacturing air bridge.

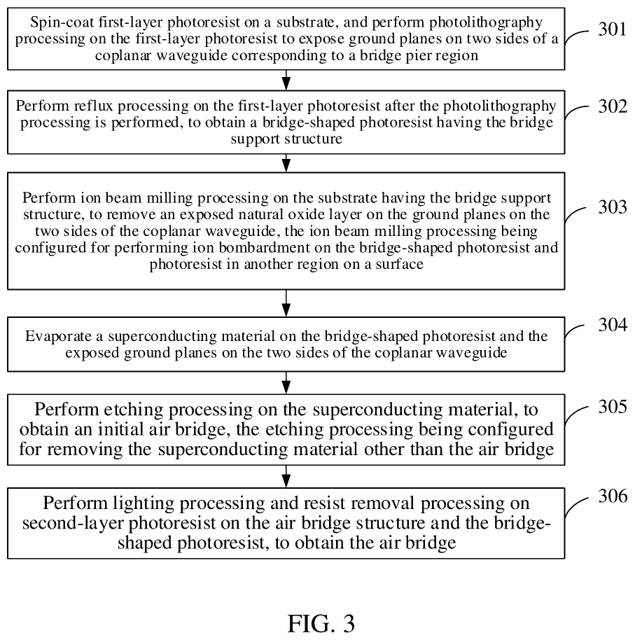

FIG. 3 is a flowchart of an air bridge preparation method according to an exemplary embodiment of the present disclosure. An example in which the method is applied to a photolithography device is used for description in this embodiment. The method includes the following operations.

Operation 301: Spin-coat first-layer photoresist on the substrate, and perform photolithography processing on the first-layer photoresist to expose ground planes on two sides of a coplanar waveguide corresponding to a bridge pier region.

In some embodiments, the photoresist may be photoresist SPR 220. In a process of preparing a bridge support structure, a photolithography device first spin-coats the first-layer photoresist on the substrate. Since a thickness of the photoresist determines a height of the air bridge, the photolithography device may control the thickness of the photoresist by controlling a photoresist spin-coating rate. In some embodiments, the thickness of the photoresist may be 3 um. Spin coating means coating the substrate with the photoresist during high-speed rotation of the substrate at a specific rotation speed, to obtain a uniform layer of photoresist.

After the spin-coating is completed, the bridge pier region needs to be photolithographed, that is, photolithography processing is performed on the first-layer photoresist, to expose the ground planes on the two sides of the coplanar waveguide that connected to the bridge pier region. In this embodiment of the present disclosure, the photoresist used is positive photoresist. During photolithography, a mask is covered on the photoresist other than a photolithography region, and then light is applied to the photolithography region to perform exposure processing.

In a possible implementation, the photolithography device may perform the exposure processing by using ultraviolet light to dissolve the photoresist in the bridge pier region, and then perform development processing, to complete the photolithography process in the bridge pier region.

Operation 302: Perform reflux processing on the first-layer photoresist after the photolithography processing is performed, to obtain bridge-shaped photoresist having the bridge support structure.

After the bridge pier area is photolithographed, the photolithography device may perform the reflux processing on remaining first-layer photoresist. Reflux is a process of baking the photoresist to a specific temperature, so that a sidewall shape of the photoresist changes.

In a possible implementation, the photolithography device may bake the photoresist SPR 220 at 140° C. for 180 s, so that the photoresist at an edge of a photolithography pattern changes from a steep straight shape to an arc shape, to obtain the bridge-shaped photoresist having the bridge support structure.

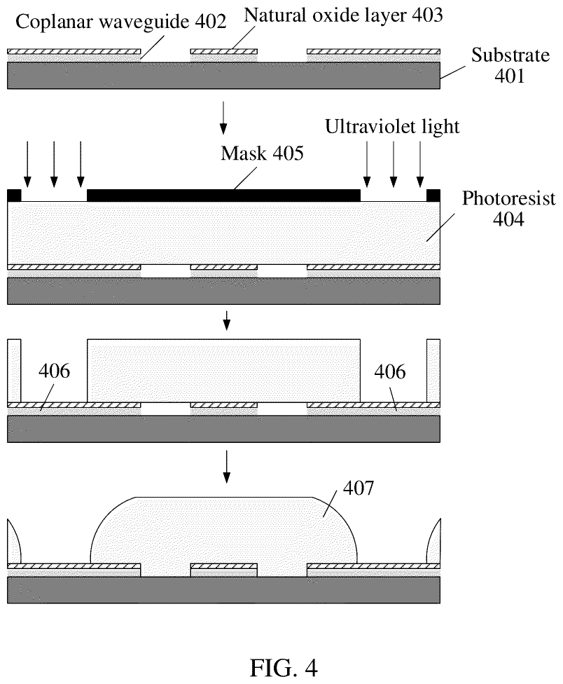

For example, FIG. 4 is a schematic diagram of a process of preparing a bridge support structure according to an embodiment of the present disclosure. A substrate 401 includes a coplanar waveguide 402. A natural oxide layer 403 is formed on the coplanar waveguide 402. The photolithography device first spins-coats first-layer photoresist 404 on the substrate 401 with the coplanar waveguide. After that, a mask 405 is covered on a region of the first-layer photoresist 404 that does not need photolithography, and then exposure processing is performed by using ultraviolet light to photolithograph the bridge pier region, to expose the coplanar waveguide 406 in the bridge pier region. After photolithography of the bridge pier region, high-temperature reflux processing is performed, to obtain bridge-shaped photoresist 407 having a bridge support structure.

Operation 303: Perform ion beam milling processing on the substrate having the bridge support structure, to remove a natural oxide layer on exposed ground planes on the two sides of the coplanar waveguide, the ion beam milling processing being configured for performing ion bombardment on the bridge-shaped photoresist and photoresist in another region on a surface.

After reflux, the photolithography device may evaporate a superconducting material on the bridge-shaped photoresist, to obtain a basic bridge body of the air bridge. Before evaporating the superconducting material, since the natural oxide layer is on the ground planes on the two sides of the coplanar waveguide that meet the bridge pier region, the photolithography device needs to first remove the natural oxide layer, so that the air bridge comes into superconducting contact with the coplanar waveguide.

In a possible implementation, the photolithography device may place the foregoing sample with the bridge-shaped photoresist into a coating machine with an ion beam milling function for vacuumizing. That is, an ion beam milling process is performed in situ on the coating machine with the ion beam milling function, to remove, through ion bombardment, the natural oxide layer of the bridge pier region that is photolithographically exposed on the coplanar waveguide. In some embodiments, the ion bombardment may be performed by using Ar ions as an ion source. “In situ” means performing multiple processes in a single vacuum chamber or in a plurality of interconnected vacuum chambers. In this embodiment, the ion beam milling process and a superconducting material evaporation process are performed in the vacuum chamber.

During ion beam milling, the ion bombardment is also performed on the bridge-shaped photoresist and photoresist in another region on the surface, to form the denatured photoresist on the surface.

Operation 304: Evaporate a superconducting material on the bridge-shaped photoresist and the exposed ground planes on the two sides of the coplanar waveguide.

After the ion beam milling process ends, the photolithography device evaporates the superconducting material in situ in the coating machine. In some embodiments, the superconducting material may be one of aluminum (Al), niobium (Nb), tantalum (Ta), and titanium nitride (TiN). A specific superconducting material is not limited in the embodiments of the present disclosure.

In a possible implementation, the photolithography device evaporates a layer of superconducting material on both the bridge-shaped photoresist and the ground planes on the two sides of the coplanar waveguide. During evaporation, regions other than the air bridge structure (the bridge body and the bridge pier) are also coated with a layer of superconducting material. Subsequently, the evaporated superconducting material is etched, to obtain the bridge body and the bridge pier of the air bridge. In some embodiments, 400 nm of Al may be used as a basic bridge body of the air bridge, for example, 400 nm of Al may be evaporated on both the bridge-shaped photoresist and the ground planes on the two sides of the coplanar waveguide.

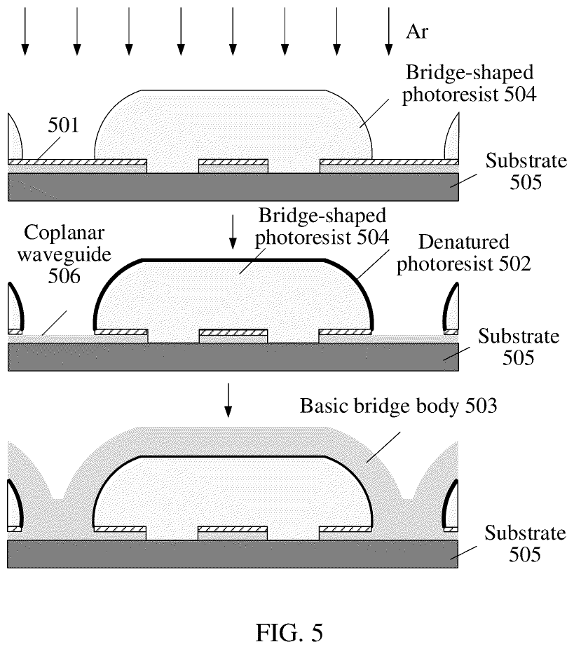

For example, as shown in FIG. 5, a substrate 505 with bridge-shaped photoresist 504 is placed into a coating machine to perform an ion beam milling process (using an Ar ion beam to bombard a sample surface), to remove a natural oxide layer 501 on ground planes on two sides of a coplanar waveguide 506 exposed after photolithography, and denatured photoresist 502 is formed on a surface of the bridge-shaped photoresist 504. Then, a superconducting material (Al) is evaporated, to obtain a basic bridge body 503.

Operation 305: Perform etching processing on the superconducting material, to obtain the initial air bridge, the etching processing being configured for removing the superconducting material other than the air bridge.

Since the evaporated superconducting material covers a layer above the entire sample, the superconducting material needs to be etched, to obtain the bridge body and the bridge pier of the air bridge. In a possible implementation, the photolithography device may remove the superconducting material other than the air bridge by using an etching solution. In addition, to prevent the bridge body and the bridge pier of the air bridge from being etched by the etching solution, the photolithography device may further cover photoresist on the bridge body and the bridge pier, to protect the bridge body and the bridge pier during etching.

A process of etching the superconducting material may include operations 305a and 305b (not shown in the figure).

Operation 305a: Spin-coat second-layer photoresist on the superconducting material, and perform photolithography processing on the second-layer photoresist other than the air bridge structure.

First, the second-layer photoresist may be spin-coated on the evaporated superconducting material. Because the bridge body and the bridge pier of the air bridge need to be protected, the photolithography device needs to perform photolithography processing on a part of the second-layer photoresist other than the air bridge structure in the second-layer photoresist.

During the photolithography, after a mask having a shape of an air bridge is covered on the second-layer photoresist, exposure processing and development processing are performed on a part of the second-layer photoresist other than the mask, to retain the photoresist on the air bridge.

Operation 305b: Perform etching processing on an exposed superconducting material by using an etching solution, to obtain the initial air bridge.

After performing the photolithography processing on the second-layer photoresist, the photolithography device may etch, by using the etching solution, the exposed superconducting material (that is, the superconducting material other than the air bridge), to obtain the initial air bridge.

In some embodiments, the etching solution may be selected based on the superconducting material. For example, when the superconducting material is Al, the superconducting material may be etched by using an Al etching solution, to retain only an air bridge part.

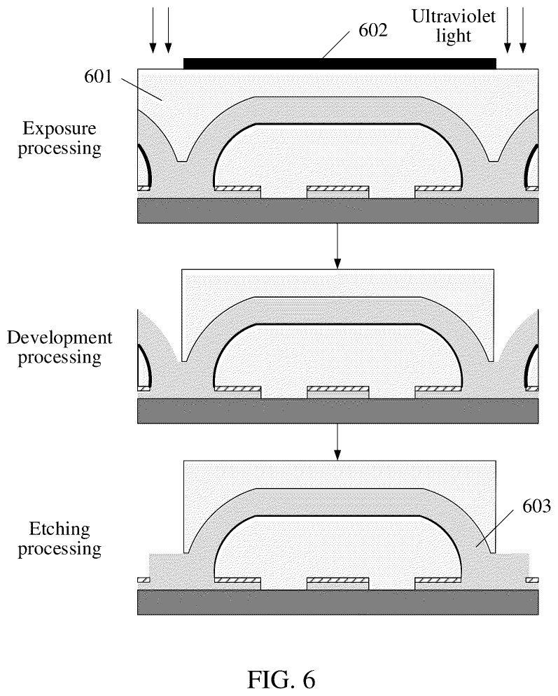

For example, as shown in FIG. 6, after a superconducting material is evaporated, second-layer photoresist 601 is spin-coated on the superconducting material, and a mask 602 in a shape of an air bridge is covered on the second-layer photoresist 601, so that the exposure processing and the development processing are performed on the second-layer photoresist 601, and after the development processing, etching processing is performed on the superconducting material, to obtain an initial air bridge 603.

The bridge-shaped photoresist and the second-layer photoresist on the air bridge structure are not removed. In other words, the photoresist region in the initial air bridge includes the bridge-shaped photoresist and the second-layer photoresist on the bridge.

Operation 306: Perform lighting processing and resist removal processing on the second-layer photoresist on the air bridge structure and the bridge-shaped photoresist, to obtain the air bridge. In some implementations, the lighting processing may be refer to a light-illuminiation processing.

After the initial air bridge is obtained, the resist removal processing is performed, to obtain the air bridge. During resist removal, the photolithography device needs to perform the lighting processing and the resist removal processing on the second-layer photoresist on the air bridge structure and the bridge-shaped photoresist, to obtain the air bridge.

In some embodiments, the air bridge may be a discrete air bridge or an integral air bridge.

When the air bridge is the integral air bridge, because a bridge body is continuous, to release the photoresist in the bridge body, hole opening processing may be performed on the bridge body of the integral air bridge in a preparation process, to improve a resist removal effect. In a possible implementation, the hole opening processing process may be performed in a process of etching the superconducting material. To be specific, for the integral air bridge, the process of etching the superconducting material includes the following operations.

Operation 1: Spin-coat second-layer photoresist on the superconducting material, and perform photolithography processing on the second-layer photoresist other than the air bridge structure.

For this process, reference may be made to the foregoing operation 305a, and details are not repeated in this embodiment.

Operation 2: Perform photolithography processing on the second-layer photoresist on a hole opening region based on a hole opening requirement of a bridge body of the air bridge.

According to the hole opening requirement, photolithography processing may be performed on the second-layer photoresist on a region on which a hole needs to be opened, to expose the superconducting material in the hole opening region, so that the superconducting material in the hole opening region is etched away.

In a possible implementation, after the photolithography processing is performed is performed on the second-layer photoresist other than the air bridge structure, the photolithography device may cover the mask that is in the shape of an air bridge and has a hole on the second-layer photoresist to perform photolithography processing. To be specific, after the photolithography processing is performed is performed on the second-layer photoresist other than the air bridge structure, the photolithography processing is performed on the second-layer photoresist on the hole opening region.

Alternatively, in another possible implementation, the photolithography device may simultaneously perform photolithography processing on the second-layer photoresist other than the air bridge structure and the photoresist of the hole opening region, that is, directly cover the mask that is in the shape of an air bridge and has a hole on the second-layer photoresist, and then perform the exposure processing and the development processing. A photolithography sequence is not limited in this embodiment.

Operation 3: Perform etching processing on the exposed superconducting material by using the etching solution, to obtain the initial air bridge including the hole.

Since the second-layer photoresist on the hole opening region is dissolved, in the process of etching the superconducting material by using the etching solution, the superconducting material in the hole opening region is also etched, and the obtained air bridge structure includes a hole, thereby helping release of the photoresist under the bridge body subsequently, and improving the resist removal effect.

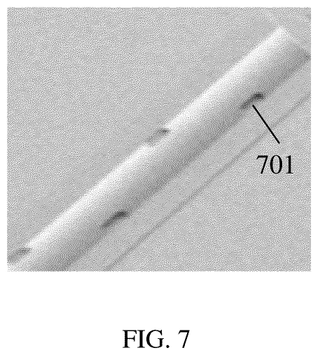

As shown in FIG. 7, a bridge body side of an integral air bridge includes a hole 701.

In the foregoing embodiment, in the process of preparing the air bridge, the first-layer photoresist is first spin-coated on the substrate, and the photolithography processing and the reflux processing are performed on the first-layer photoresist, to obtain the bridge-shaped photoresist having the bridge support structure. The ion beam milling processing is performed on the substrate having the bridge support structure, and the superconducting material is evaporated on the bridge-shaped photoresist and the exposed ground planes on the two sides of the coplanar waveguide. Moreover, the second-layer photoresist is spin-coated on the superconducting material, the photolithography processing is also performed on the second-layer photoresist, and the etching processing is performed on the exposed superconducting material, to obtain the initial air bridge. The lighting processing and the resist removal processing are performed on the second-layer photoresist and the bridge-shaped photoresist on the air bridge structure, to obtain the air bridge. After the first-layer photoresist is spin-coated, the corresponding photolithography processing, reflux processing, ion beam milling processing are first performed, the second-layer photoresist is then spin-coated on the superconducting material, and the photolithography processing and the etching processing are performed, to obtain the initial air bridge, thereby improving a success rate of air bridge preparation.

In the foregoing embodiments, the preparation process of the air bridge structure is exemplarily described. The resist removal process is described below in detail.

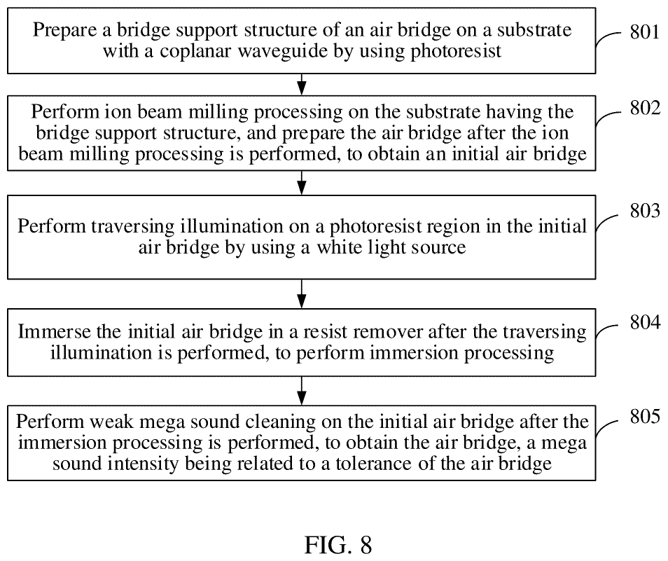

FIG. 8 is a flowchart of an air bridge preparation method according to an exemplary embodiment of the present disclosure. The method includes the following operations.

Operation 801: Prepare a bridge support structure of an air bridge on a substrate with a coplanar waveguide by using photoresist.

Operation 802: Perform ion beam milling processing on the substrate having the bridge support structure, and prepare the air bridge after the ion beam milling processing is performed, to obtain an initial air bridge.

For implementations of operation 801 and operation 802, reference may be made to operation 301 to operation 305 in the foregoing embodiment. Details are not repeated in this embodiment.

Operation 803: Perform traversing illumination on a photoresist region in the initial air bridge by using a white light source.

In a possible implementation, the white light source may be provided by a microscope device. During the traversing illumination by using the microscope, an illumination spot size ranges from 2 mm to 3 mm. Therefore, the photolithography device needs to traverse the photoresist regions in the initial air bridge one by one by using the white light source.

For example, the microscope device may be a Zeiss Smartzoom microscope device, so that the photolithography device may traverse the photoresist regions one by one in the initial air bridge by using a white light source provided by the Zeiss Smartzoom microscope device, and illumination duration for each region may be 0.5 s.

In some embodiments, the white light source may alternatively be provided by another component or device, for example, may be provided by an incandescent lamp. This is not limited in this embodiment.

Operation 804: Immerse the initial air bridge in a resist remover after the traversing illumination is performed, to perform immersion processing.

After the traversing illumination is performed is completed, resist removal processing may be performed on the photoresist region. In a possible implementation, the photolithography device may use a wet resist removal manner. To be specific, the initial air bridge after the traversing illumination is performed is immersed in a resist remover, to perform resist removal.

In some embodiments, the resist remover may be a Remover PG resist remover, or an NMP resist remover.

To further improve the resist removal effect, in another possible implementation, the photolithography device may first immerse the initial air bridge after the traversing illumination is performed in an isopropanol solution before immersing the initial air bridge after the traversing illumination is performed in the resist remover. In other words, the initial air bridge after the traversing illumination is performed is immersed in the isopropanol solution for immersion processing.

For example, the photolithography device may immerse the initial air bridge after the traversing illumination is performed in the isopropanol solution at ordinary temperature for three hours, then transfer the initial air bridge to the resist remover for immersion. The initial air bridge is immersed in the resist remover heated at 80° C. for six hours, or may be immersed in the resist remover at room temperature.

Operation 805: Perform weak mega sound cleaning on the initial air bridge after the immersion processing is performed, to obtain the air bridge, a mega sound intensity being related to a tolerance of the air bridge.

Since some residual photoresist may still exist in the initial air bridge after the immersion processing is performed, to remove the residual photoresist and optimize the resist removal effect, the photolithography device may further perform, by using a mega sound cleaning machine, weak mega sound cleaning on the initial air bridge after the immersion processing is performed.

In some embodiments, the weak mega sound cleaning may refer to a mega sound cleaning process by using mega sound at a frequency less than 1500 KHz and a power less than 75 W. The mega sound intensity is related to the tolerance of the air bridge, and the mega sound intensity may be adjusted according to the tolerance of the air bridge. Further, the mega sound intensity may be determined according to a tolerance of the integral air bridge, to avoid causing collapse of the air bridge. In some embodiments, the mega sound intensity is also related to density of the bridge body. When the density of the bridge body is higher, the mega sound intensity is higher. For example, cleaning may be performed by using the mega sound cleaning machine at 1000 kHz and 50 W for 20 minutes.

In a possible implementation, after performing the weak mega sound cleaning on the initial air bridge after the immersion processing is performed, the photolithography device may further use the isopropanol solution to wash the air bridge after the weak mega sound cleaning is performed, and perform drying processing by using dry nitrogen, to obtain the air bridge.

That the air bridge after the weak mega sound cleaning is performed is washed by using the isopropanol solution is mainly to remove the resist remover on the air bridge. In addition, because the isopropanol solution is volatile, the isopropanol solution can be used to remove the resist remover. After washing is completed, the photolithography device then performs drying processing on the air bridge after the washing by using the dry nitrogen, to complete preparation of the air bridge.

In the foregoing process, after the traversing illumination is performed by using the white light source, the air bridge is then immersed in the resist remover to perform resist removal processing. In another possible implementation, to shorten resist removal time and improve resist removal efficiency, the photolithography device may alternatively synchronize the traversing illumination process by using the white light source and the immersion process by using the resist remover. In this manner, operations 803 to 805 may be replaced with the following operations.

Operation 1: Immerse the initial air bridge in the resist remover, and perform, by using the white light source, traversing illumination on the initial air bridge immersed in the resist remover.

The photolithography device may immerse the initial air bridge in the resist remover, and perform, by using the white light source, traversing illumination on the photoresist region in the air bridge during immersion.

Operation 2: Perform weak mega sound cleaning on the initial air bridge after the immersion processing is performed, to obtain the air bridge.

After the immersion ends, the photolithography device may perform weak mega sound cleaning on the initial air bridge after the immersion processing is performed. In some embodiments, cleaning may be performed by using a mega sound cleaning machine at 1000 kHz and 50 W for 20 minutes.

After the cleaning is completed, the isopropanol solution is used for washing, and the air bridge is dried by using the dry nitrogen, to complete the preparation of the air bridge.

In this embodiment, the traversing illumination is performed on the photoresist region by using the white light source, and the immersion processing is then performed by using the isopropanol solution and the resist remover. The resist removal can be completed through the weak mega sound cleaning, and the denatured photoresist in a region meeting the air bridge structure is removed. This can improve the resist removal effect, and is conducive to improving performance of a superconducting quantum chip. In addition, an operation is simple, so that the resist removal time can be significantly reduced, and the resist removal efficiency can be improved. In this process, the resist can be removed completely through only the weak mega sound cleaning, avoiding causing collapse of the air bridge, and improving a success rate of the air bridge.

In addition, processes of the traversing illumination by using white light and the immersion by using the resist remover may alternatively be performed at the same time, thereby further reducing the resist removal time and improving the resist removal efficiency.

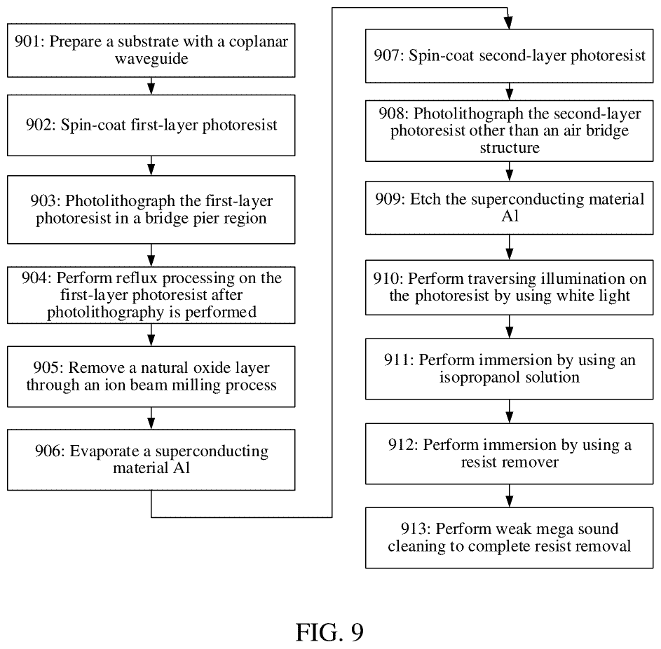

FIG. 9 is a flowchart of a complete preparation procedure of an air bridge according to an exemplary embodiment of the present disclosure. A process includes the following operations.

Operation 901: Prepare a substrate with a coplanar waveguide.

In some embodiments, the photolithography device may prepare the substrate by using a high-resistance silicon substrate or a sapphire substrate. The coplanar waveguide is prepared by using a superconducting material.

Operation 902: Spin-coat first-layer photoresist.

In some embodiments, the photolithography device may spin-coat 3 μm of photoresist SPR 220 on the substrate.

Operation 903: Photolithograph the first-layer photoresist in a bridge pier region.

The photolithography device first needs to perform photolithography processing on the first-layer photoresist in the bridge pier region, to expose a ground plane of the coplanar waveguide, so that the ground plane meets a bridge pier of an air bridge.

Operation 904: Perform reflux processing on the first-layer photoresist after photolithography.

The photolithography device may bake the photoresist SPR 220 at 140° C. for 180 s to obtain bridge-shaped photoresist.

Operation 905: Remove a natural oxide layer through an ion beam milling process.

In some embodiments, the photolithography device may perform ion bombardment by using Ar as an ion source, to remove the natural oxide layer in the bridge pier area.

Operation 906: Evaporate a superconducting material Al.

In some embodiments, the photolithography device may evaporate 400 nm of Al in-situ by using a coating machine.

Operation 907: Spin-coat second-layer photoresist.

Operation 908: Photolithograph the second-layer photoresist other than an air bridge structure.

Operation 909: Etch the superconducting material Al.

In some embodiments, the photolithography device may perform etching by using an Al etching solution. The superconducting material other than the air bridge structure (including a bridge body and a bridge pier) is etched.

Operation 910: Perform traversing illumination on the photoresist by using white light.

In some embodiments, the photolithography device may perform the traversing illumination on a photoresist region by using a Zeiss Smartzoom microscope, and each region is illuminated for 0.5 s.

Operation 911: Perform immersion by using an isopropanol solution.

In some embodiments, the photolithography device may perform immersion by using the isopropanol solution at an ordinary temperature for three hours.

Operation 912: Perform immersion by using a resist remover.

In some embodiments, the photolithography device may perform immersion by using a resist remover of Remover PG heated at 80° C. for six hours, or perform immersion at room temperature for six hours.

Operation 913: Perform weak mega sound cleaning to complete resist removal.

In some embodiments, the photolithography device may perform cleaning by using a mega sound cleaning machine at 1000 kHz and 50 W for 20 minutes. and perform washing by using an isopropanol solution, and then perform drying by using dry nitrogen, to obtain the air bridge.

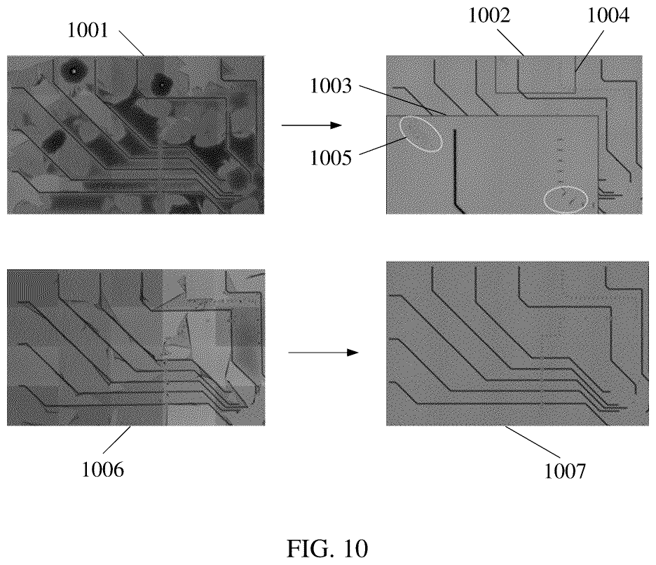

For example, FIG. 10 is a diagram of comparison between a remover effect of a conventional resist remover and a remover effect of a resist removal method provided in the present disclosure. During resist removal by using the conventional resist remover, a first microscope photo 1001 is a microscope photo after immersion at 80° C. for ten hours by using a conventional resist remover of Remover PG, and a second microscope photo 1002 is a microscope photo after cleaning at 1000 kHz and 50 W for 20 minutes. A region 1003 is a region obtained by enlarging a region 1004 in the second microscope photo 1002, and it can be seen that residual photoresist 1005 still exists.

During resist removal process by using the resist removal method provided in the embodiments of the present disclosure, a third microscope photo 1006 is a microscope photo after traversing illumination is performed on a sample by using white light, and the sample is immersed in the isopropanol solution for three hours, and is then immersed in the Remover PG at 80° C. for seven hours. A fourth microscope photo 1007 is a microscope photo after cleaning is performed at 1000 kHz and 50 W for 20 minutes. In this case, the resist is completely removed.

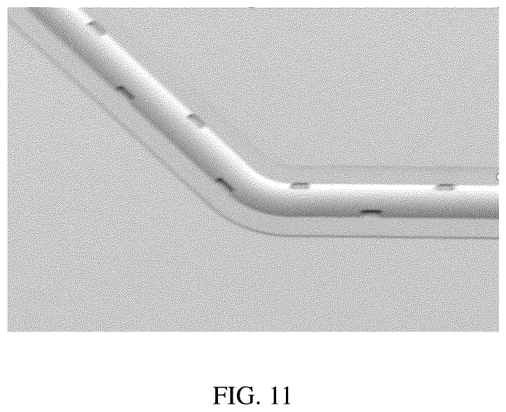

FIG. 11 is a scan electron microscope picture of an integral air bridge after resist removal by using the resist removal method provided in this embodiment of the present disclosure. This has a good resist removal effect.

According to the method provided in the embodiments of the present disclosure, resist remover immersion time can be reduced, resist removal efficiency can be improved, and denatured photoresist can be removed, thereby improving a resist removal effect.

In the foregoing embodiments, photoresist in a photoresist-based air bridge is removed all by using the resist removal method. In another possible case, the resist removal method may also be used in a SiO₂-based air bridge preparation process. In the SiO₂-based air bridge preparation process, the photoresist also needs to be used, and an ion beam milling process is also required to remove a natural oxide layer, causing denaturation of a surface of the photoresist. Therefore, during resist removal, white light may be used for traversing illumination, to remove denatured photoresist in a region meeting the air bridge structure, thereby improving a resist removal effect.

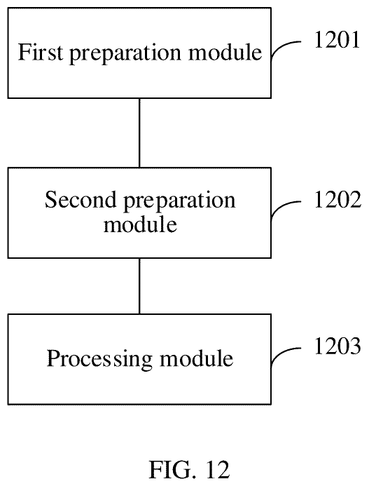

FIG. 12 is a structural block diagram of an air bridge preparation apparatus according to an embodiment of the present disclosure. The apparatus includes:
a first preparation module 1201, configured to prepare a bridge support structure of an air bridge on a substrate with a coplanar waveguide by using photoresist;
a second preparation module 1202, configured to perform ion beam milling processing on the substrate having the bridge support structure, and prepare the air bridge after the ion beam milling processing is performed, to obtain an initial air bridge, the ion beam milling processing being configured for denaturing photoresist on a surface layer of the bridge support structure; and
a processing module 1203, configured to perform lighting processing and resist removal processing on a photoresist region including denatured photoresist in the initial air bridge, to obtain the air bridge.

In some embodiments, the processing module 1203 is configured to:
perform traversing illumination on the photoresist region in the initial air bridge by using a white light source;
immerse the initial air bridge in a resist remover after the traversing illumination is performed, to perform immersion processing; and
perform weak mega sound cleaning on the initial air bridge after the immersion processing is performed, to obtain the air bridge, a mega sound intensity being related to a tolerance of the air bridge.

In some embodiments, after the traversing illumination is performed is performed on the photoresist region in the initial air bridge by using the white light source, the apparatus further includes:

an immersion processing module, configured to immerse the initial air bridge in an isopropanol solution after the traversing illumination is performed, to perform immersion processing.

In some embodiments, the processing module 1203 is configured to:
immerse the initial air bridge in the resist remover, and perform, by using the white light source, traversing illumination on the initial air bridge immersed in the resist remover; and
perform weak mega sound cleaning on the initial air bridge after the immersion processing is performed, to obtain the air bridge.

In some embodiments, after the weak mega sound cleaning is performed is performed on the initial air bridge after the immersion processing is performed, the apparatus further includes:

a washing and drying module, configured to wash, by using the isopropanol solution, the air bridge after the weak mega sound cleaning is performed, and perform drying processing by using dry nitrogen, to obtain the air bridge.

In some embodiments, the white light source is provided by a microscope device.

In some embodiments, a mega sound frequency of the weak mega sound cleaning is less than 1500 kHz, and a power of the weak mega sound cleaning is less than 75 W.

In some embodiments, the first preparation module 1201 is configured to:
spin-coat first-layer photoresist on the substrate, and perform photolithography processing on the first-layer photoresist to expose ground planes on two sides of a coplanar waveguide corresponding to a bridge pier region; and
perform reflux processing on the first-layer photoresist after the photolithography processing is performed, to obtain bridge-shaped photoresist having the bridge support structure.

In some embodiments, the second preparation module 1202 is configured to:
perform ion beam milling processing on the substrate having the bridge support structure, to remove a natural oxide layer on exposed ground planes on the two sides of the coplanar waveguide, during the ion beam milling processing, ion bombardment being performed on the bridge-shaped photoresist and photoresist in another region on a surface;
evaporate a superconducting material on the bridge-shaped photoresist and the exposed ground planes on the two sides of the coplanar waveguide; and
perform etching processing on the superconducting material, to obtain the initial air bridge, the etching processing being configured for removing the superconducting material other than the air bridge.

In some embodiments, the second preparation module 1202 is further configured to:
spin-coat second-layer photoresist on the superconducting material, and perform photolithography processing on the second-layer photoresist other than the air bridge structure; and
perform etching processing on an exposed superconducting material by using an etching solution, to obtain the initial air bridge.

In some embodiments, the processing module 1203 is configured to:
perform lighting processing and resist removal processing on the second-layer photoresist on the air bridge structure and the bridge-shaped photoresist, to obtain the air bridge.

In some embodiments, the air bridge is a discrete air bridge or an integral air bridge.

In some embodiments, the air bridge is an integral air bridge, and before the etching processing is performed on the exposed superconducting material by using the etching solution, the apparatus further includes
a photolithography processing module, configured to perform photolithography processing on the second-layer photoresist on a hole opening region based on a hole opening requirement of a bridge body of the air bridge.

The second preparation module 1202 is further configured to perform etching processing on the exposed superconducting material by using the etching solution, to obtain the initial air bridge including a hole.

An embodiment of the present disclosure further provides a photolithography device. The photolithography device includes a photolithography component, a processor, and a memory. The memory has at least one instruction stored therein. The at least one instruction is loaded by the processor and controls the photolithography component, to implement the air bridge preparation method according to the foregoing embodiments.

An embodiment of the present disclosure further provides a quantum chip, including an air bridge prepared through the air bridge preparation method in the foregoing embodiments.

An embodiment of the present disclosure further provides a quantum computer, including the quantum chip according to the foregoing embodiment.

In various embodiments in the present disclosure, a module may refer to a software module, a hardware module, or a combination thereof. A software module may include a computer program or part of the computer program that has a predefined function and works together with other related parts to achieve a predefined goal, such as those functions described in this disclosure. A hardware module may be implemented using processing circuitry and/or memory configured to perform the functions described in this disclosure. Each module can be implemented using one or more processors (or processors and memory). Likewise, a processor (or processors and memory) can be used to implement one or more modules. Moreover, each module can be part of an overall module that includes the functionalities of the module. The description here also applies to the term module and other equivalent terms.

In some other embodiments, a computer-readable medium comprising instructions which, when executed by a computer, cause the computer to carry out a portion or all of the above methods. The computer-readable medium may be referred as non-transitory computer-readable media (CRM) that stores data for extended periods such as a flash drive or compact disk (CD), or for short periods in the presence of power such as a memory device or random access memory (RAM). In some embodiments, computer-readable instructions may be included in a software, which is embodied in one or more tangible, non-transitory, computer-readable media. Such non-transitory computer-readable media can be media associated with user-accessible mass storage as well as certain short-duration storage that are of non-transitory nature, such as internal mass storage or ROM. The software implementing various embodiments of the present disclosure can be stored in such devices and executed by a processor (or processing circuitry). A computer-readable medium can include one or more memory devices or chips, according to particular needs. The software can cause the processor (including CPU, GPU, FPGA, and the like) to execute particular processes or particular parts of particular processes described herein, including defining data structures stored in RAM and modifying such data structures according to the processes defined by the software. In various embodiments in the present disclosure, the term “processor” may mean one processor that performs the defined functions, steps, or operations or a plurality of processors that collectively perform defined functions, steps, or operations, such that the execution of the individual defined functions may be divided amongst such plurality of processors.

The foregoing descriptions are merely exemplary embodiments of the present disclosure, but are not intended to limit the present disclosure. Any modification, equivalent replacement, or improvement made within the spirit and principle of the present disclosure shall fall within the protection scope of the present disclosure.

What is claimed is:

1. A method for manufacturing an air bridge, performed by a photolithography device, the method comprising:
constructing a bridge support structure for an air bridge on a substrate with a coplanar waveguide by using photoresist;
performing ion beam milling processing on the substrate with the bridge support structure to obtain an initial air bridge, the ion beam milling processing being configured for denaturing photoresist on a surface layer of the bridge support structure; and
performing light-illumination processing and photoresist removal processing on a photoresist region comprising denatured photoresist in the initial air bridge, to obtain the air bridge.

2. The method according to claim 1, wherein the performing light-illumination processing and photoresist removal processing on the photoresist region comprising denatured photoresist in the initial air bridge, to obtain the air bridge comprises:
applying traversing illumination on the photoresist region in the initial air bridge by using a white light source;
immersing the initial air bridge in a resist remover after the traversing illumination is performed, to perform immersion processing; and
performing weak mega sound cleaning on the initial air bridge after the immersion processing is performed, to obtain the air bridge, a mega sound intensity being related to a tolerance of the air bridge.

3. The method according to claim 2, wherein, after the applying traversing illumination on the photoresist region in the initial air bridge by using the white light source, the method further comprises:
immersing the initial air bridge in an isopropanol solution after the traversing illumination is performed, to perform immersion processing.

4. The method according to claim 1, wherein the performing the light-illumination processing and photoresist removal processing on the photoresist region comprising denatured photoresist in the initial air bridge, to obtain the air bridge comprises:
immersing the initial air bridge in a resist remover;
applying, by using a white light source, traversing illumination on the initial air bridge immersed in the resist remover; and
performing weak mega sound cleaning on the initial air bridge after the immersion processing is performed, to obtain the air bridge.

5. The method according to claim 2, wherein, after the performing weak mega sound cleaning on the initial air bridge after the immersion processing is performed, the method further comprises:
washing, by using an isopropanol solution, the air bridge, and
performing drying processing by using dry nitrogen, to obtain the air bridge.

6. The method according to claim 2, wherein the white light source is provided by a microscope device.

7. The method according to claim 2, wherein a mega sound frequency of the weak mega sound cleaning is less than 1500 kHz, and a power of the weak mega sound cleaning is less than 75 W.

8. The method according to claim 1, wherein the constructing the bridge support structure of the air bridge on the substrate with the coplanar waveguide by using photoresist comprising:
spin-coating first-layer photoresist on the substrate, and performing photolithography processing on the first-layer photoresist to expose ground planes on two sides of a coplanar waveguide corresponding to a bridge pier region; and
performing reflux processing on the first-layer photoresist after the photolithography processing is performed, to obtain bridge-shaped photoresist having the bridge support structure.

9. An apparatus for manufacturing an air bridge, comprising:
a photolithography device;
a memory storing instructions; and
a processor in communication with the memory, wherein, when the processor executes the instructions, the processor is configured to cause the photolithography device to:
construct a bridge support structure for an air bridge on a substrate with a coplanar waveguide by using photoresist;
perform ion beam milling processing on the substrate with the bridge support structure to obtain an initial air bridge, the ion beam milling processing being configured for denaturing photoresist on a surface layer of the bridge support structure; and
perform light-illumination processing and photoresist removal processing on a photoresist region comprising denatured photoresist in the initial air bridge, to obtain the air bridge.

10. The apparatus according to claim 9, wherein, when the processor is configured to cause the photolithography device to perform light-illumination processing and photoresist removal processing on the photoresist region comprising denatured photoresist in the initial air bridge, to obtain the air bridge, the processor is configured to cause the photolithography device to:
apply traversing illumination on the photoresist region in the initial air bridge by using a white light source;
immerse the initial air bridge in a resist remover after the traversing illumination is performed, to perform immersion processing; and
perform weak mega sound cleaning on the initial air bridge after the immersion processing is performed, to obtain the air bridge, a mega sound intensity being related to a tolerance of the air bridge.

11. The apparatus according to claim 10, wherein, after the processor is configured to cause the photolithography device to apply traversing illumination on the photoresist region in the initial air bridge by using the white light source, the processor is further configured to cause the photolithography device to:
immerse the initial air bridge in an isopropanol solution after the traversing illumination is performed, to perform immersion processing.

12. The apparatus according to claim 9, wherein, when the processor is configured to cause the photolithography device to perform the light-illumination processing and photoresist removal processing on the photoresist region comprising denatured photoresist in the initial air bridge, to obtain the air bridge, the processor is configured to cause the photolithography device to:
immerse the initial air bridge in a resist remover;
apply, by using a white light source, traversing illumination on the initial air bridge immersed in the resist remover; and
perform weak mega sound cleaning on the initial air bridge after the immersion processing is performed, to obtain the air bridge.

13. The apparatus according to claim 10, wherein, after the processor is configured to cause the photolithography device to perform weak mega sound cleaning on the initial air bridge after the immersion processing is performed, the processor is further configured to cause the photolithography device to:
wash, by using an isopropanol solution, the air bridge, and
perform drying processing by using dry nitrogen, to obtain the air bridge.

14. The apparatus according to claim 10, wherein the white light source is provided by a microscope device.

15. The apparatus according to claim 10, wherein a mega sound frequency of the weak mega sound cleaning is less than 1500 kHz, and a power of the weak mega sound cleaning is less than 75 W.

16. The apparatus according to claim 9, wherein, when the processor is configured to cause the photolithography device to construct the bridge support structure of the air bridge on the substrate with the coplanar waveguide by using photoresist, the processor is configured to cause the photolithography device to:
spin-coat first-layer photoresist on the substrate, and performing photolithography processing on the first-layer photoresist to expose ground planes on two sides of a coplanar waveguide corresponding to a bridge pier region; and
perform reflux processing on the first-layer photoresist after the photolithography processing is performed, to obtain bridge-shaped photoresist having the bridge support structure.

17. A non-transitory computer-readable storage medium, storing computer-readable instructions, wherein, the computer-readable instructions, when executed by a processor in an apparatus comprising a photolithography device, are configured to cause the photolithography device to:
construct a bridge support structure for an air bridge on a substrate with a coplanar waveguide by using photoresist;
perform ion beam milling processing on the substrate with the bridge support structure to obtain an initial air bridge, the ion beam milling processing being configured for denaturing photoresist on a surface layer of the bridge support structure; and
perform light-illumination processing and photoresist removal processing on a photoresist region comprising denatured photoresist in the initial air bridge, to obtain the air bridge.

18. The non-transitory computer-readable storage medium according to claim 17, wherein, when the computer-readable instructions are configured to cause the photolithography device to perform light-illumination processing and photoresist removal processing on the photoresist region comprising denatured photoresist in the initial air bridge, to obtain the air bridge, the computer-readable instructions are configured to cause the photolithography device to:
apply traversing illumination on the photoresist region in the initial air bridge by using a white light source;
immerse the initial air bridge in a resist remover after the traversing illumination is performed, to perform immersion processing; and
perform weak mega sound cleaning on the initial air bridge after the immersion processing is performed, to obtain the air bridge, a mega sound intensity being related to a tolerance of the air bridge.

19. The non-transitory computer-readable storage medium according to claim 18, wherein, after the computer-readable instructions are configured to cause the photolithography device to apply traversing illumination on the photoresist region in the initial air bridge by using the white light source, the computer-readable instructions are further configured to cause the photolithography device to:
immerse the initial air bridge in an isopropanol solution after the traversing illumination is performed, to perform immersion processing.

20. The non-transitory computer-readable storage medium according to claim 17, wherein, when the computer-readable instructions are configured to cause the photolithography device to perform the light-illumination processing and photoresist removal processing on the photoresist region comprising denatured photoresist in the initial air bridge, to obtain the air bridge, the computer-readable instructions are configured to cause the photolithography device to:
immerse the initial air bridge in a resist remover,
apply, by using a white light source, traversing illumination on the initial air bridge immersed in the resist remover, and
perform weak mega sound cleaning on the initial air bridge after the immersion processing is performed, to obtain the air bridge.
